(19) United States
(12) Patent Application Publication
(10) Pub. No.: US 2022/0140220 A1
(43) Pub. Date: May 5, 2022

(54) THERMOELECTRIC MODULE

(71) Applicant: LG INNOTEK CO., LTD., Seoul (KR)

(72) Inventors: Jong Hyun KIM, Seoul (KR); Myoung Lae ROH, Seoul (KR)

(21) Appl. No.: 17/431,783

(22) PCT Filed: Feb. 26, 2020
(86) PCT No.: PCT/KR2020/002720

§ 371 Date: Aug. 18, 2021

(30) Foreign Application Priority Data
Feb. 26, 2019 (KR) 10-2019-0022586
Feb. 28, 2019 (KR) 10-2019-0024010

(51) Int. Cl. H01L 35/32; H01L 35/30; H01L 35/10

(52) U.S. Cl. CPC H01L 35/32; H01L 35/10; H01L 35/30

(57) ABSTRACT

A thermoelectric module according to an embodiment of the present invention comprises: a housing, a thermoelectric element accommodated in the housing; a sealing member disposed on a side portion of the thermoelectric element; and a heat transfer member disposed on the thermoelectric element. The thermoelectric element includes: a first substrate; a plurality of first electrodes disposed on the first substrate; a plurality of thermoelectric legs disposed on the plurality of first electrodes; a plurality of second electrodes disposed on the plurality of thermoelectric legs; and a second substrate disposed on the second electrodes. The heat transfer member includes a plurality of grooves, and the sealing member is in contact with a side surface of at least one of the first electrodes, the second electrodes, and the plurality of thermoelectric legs.

### TECHNICAL FIELD

The present invention relates to a thermoelectric module.

### BACKGROUND ART

A thermoelectric phenomenon is a phenomenon which occurs due to movement of electrons and holes in a material and refers to direct energy conversion between heat and electricity.

A thermoelectric element is a generic term for an element using the thermoelectric phenomenon and has a structure in which a P-type thermoelectric material and an N-type thermoelectric material are joined between metal electrodes to form a PN junction pair.

Thermoelectric elements can be classified into an element using temperature changes of electrical resistance, an element using the Seebeck effect, which is a phenomenon in which an electromotive force is generated due to a temperature difference, an element using the Peltier effect, which is a phenomenon in which heat absorption or heating due to current occurs, and the like.

The thermoelectric element is variously applied to home appliances, electronic components, communication components, outdoor products, or the like. For example, the thermoelectric element can be applied to a cooling and heating device, a power generation device, or the like.

When the thermoelectric element is applied to the cooling and heating device, air introduced into the device is cooled at a low-temperature part of the thermoelectric element, heated at a high-temperature part, and then discharged. In this case, a temperature of the low-temperature part is lower than that of surrounding air, and a temperature of the high-temperature part is higher than that of the surrounding air, and in this case, a heat transfer member is installed on a low-temperature part substrate and a high-temperature part substrate so that a heat exchange with the surrounding air is advantageous.

Cooling performance or heating performance of the thermoelectric module is improved as the heat exchange between the heat transfer member and the surrounding air becomes smooth. In this case, when heat exchange between the heat transfer member installed on the low-temperature part substrate and the surrounding air is not sufficient, there is a problem in that cooling performance of the low-temperature part is lowered and the performance of the thermoelectric module is lowered. Accordingly, a heat exchange structure design of the heat transfer member to improve the performance of the thermoelectric module is required.

### DISCLOSURE

### Technical Problem

The present invention is directed to providing a heat exchange structure of a thermoelectric module.

### Technical Solution

A thermoelectric module according to an embodiment of the present invention includes: a housing; a thermoelectric element accommodated in the housing; a sealing member disposed on a peripheral of the thermoelectric element; and a heat transfer member disposed on the thermoelectric element, wherein the thermoelectric element includes a first substrate, a plurality of first electrodes disposed on the first substrate, a plurality of thermoelectric legs disposed on the plurality of first electrodes, a plurality of second electrodes disposed on the plurality of thermoelectric legs, and a second substrate disposed on the second electrodes, the heat transfer member includes a plurality of grooves, and the sealing member comes into contact with a side surface of at least one of the first electrodes, the second electrodes, and the plurality of thermoelectric legs.

The heat transfer member may include a first heat transfer member disposed under the first substrate, and a second heat transfer member disposed on the second substrate.

The heat transfer member may include a plurality of protruding patterns respectively disposed adjacent to the grooves thereof, and the protruding patterns may be disposed to have a constant inclination angle with respect to a direction in which air enters an air flow path.

The first substrate may be a low-temperature part, the second substrate may be a high-temperature part, a surface area of the first heat transfer member may be larger than a surface area of the second heat transfer member, and a ratio of the surface area of the first heat transfer member to the surface area of the second heat transfer member may be 1.1 to 5.

At least one of the first heat transfer member and the second heat transfer member may be disposed so that a plurality of plate-shaped base substrates may be spaced apart from each other, the plurality of plate-shaped base substrates may include at least one bent portion, and the number of bent portions included in the first heat transfer member may be greater than the number of bent portions included in the second heat transfer member.

At least one of the first heat transfer member and the second heat transfer member may include a plurality of folding units in which the plate-shaped base substrate is regularly folded to have a predetermined interval, the plurality of folding units may include at least one bent portion, and the number of bent portions included in the first heat transfer member may be greater than the number of bent portions included in the second heat transfer member.

The bent portion may be plural, and the plurality of bent portions may be repeatedly disposed along an air flow path direction.

The bent portion may be plural, and the plurality of bent portions may be repeatedly disposed along a direction from the first substrate to the first heat transfer member or a direction from the second substrate to the second heat transfer member.

The housing may include a first housing and a second housing, a first heat transfer member may be disposed in the first housing, a second heat transfer member may be disposed in the second housing, a volume of an inner space of the first housing may be larger than a volume of an inner space of the second housing, and a ratio of the volume of the inner space of the first housing to the volume of the inner space of the second housing may be 1.1 to 3.

The housing may further include an isolation member disposed between the first housing and the second housing to isolate the first housing and the second housing from each other, and the isolation member may be connected to one of the first substrate and the second substrate, or disposed between the first substrate and the second substrate.

### Advantageous Effects

In a thermoelectric module according to an embodiment of the present invention, a heat exchange area and a heat exchange time of a heat exchange member of a low-temperature part can be increased to lower a cooling temperature of the low-temperature part to a lower temperature, and thus the cooling performance of the thermoelectric module can be improved.

Specifically, since a heat exchange area and a heat exchange time of a heat exchange member of a low-temperature part compared to a high-temperature part can be increased, the performance of the thermoelectric module can be further improved by improving cooling efficiency of the low-temperature part while reducing heat interference due to the heat generation of the high-temperature part.

In the thermoelectric module according to an embodiment of the present invention, it is possible to improve the performance of the thermoelectric module while maintaining productivity of the thermoelectric module by increasing a heat exchange area compared to an occupied area of a heat exchange member.

### DESCRIPTION OF DRAWINGS

FIG. 1 is a cross-sectional view of a thermoelectric module according to one embodiment of the present invention.

FIG. 2 is a perspective view of the thermoelectric module according to one embodiment of the present invention.

FIG. 3 is an exploded perspective view of the thermoelectric module according to one embodiment of the present invention.

FIG. 4 is a perspective view of the thermoelectric module according to one embodiment of the present invention.

FIGS. 5 and 6 illustrate a heat transfer member included in the thermoelectric module according to one embodiment of the present invention.

FIGS. 7A to 7D, 8, 9 and 10 are modified examples of a first heat transfer member included in the thermoelectric module according to one embodiment of the present invention.

FIGS. 11 and 12 are modified examples of a first heat transfer member included in a thermoelectric module according to another embodiment of the present invention.

FIGS. 13 and 14 are modified examples of a first heat transfer member included in a thermoelectric module according to still another embodiment of the present invention.

FIG. 15 is a cross-sectional view of a cooling and heating device including the thermoelectric module according to one embodiment of the present invention.

FIG. 16 is a side cross-sectional view of the cooling and heating device according to one embodiment of the present invention.

FIGS. 17 to 20 are various modified examples of a housing included in the cooling and heating device according to one embodiment.

### MODES OF THE INVENTION

Hereinafter, preferred embodiments of the present invention will be described in detail with reference to the accompanying drawings.

However, the technical spirit of the present invention is not limited to some embodiments which will be described and may be embodied in various forms, and one or more elements in the embodiments may be selectively combined and replaced to be used within the scope of the technical spirit of the present invention.

Further, terms used in the embodiments of the present invention (including technical and scientific terms), may be interpreted with meanings that are generally understood by those skilled in the art unless particularly defined and described, and terms which are generally used, such as terms defined in a dictionary, may be understood in consideration of their contextual meanings in the related art.

In addition, terms used in the description are provided not to limit the present invention but to describe the embodiments.

In the specification, the singular form may also include the plural form unless the context clearly indicates otherwise and may include one or more of all possible combinations of A, B, and C when disclosed as at least one (or one or more) of “A, B, and C”.

Further, terms such as first, second, A, B, (a), (b), and the like may be used to describe elements of the embodiments of the present invention.

The terms are only provided to distinguish an element from other elements, and the essence, sequence, order, or the like of the elements is not limited by the terms.

Further, when a particular element is disclosed as being “connected,” “coupled,” or “linked” to another element, this may not only include a case of the element being directly connected, coupled, or linked to the other element but also a case of the element being connected, coupled, or linked to the other element by another element between the element and the other element.

In addition, when one element is disclosed as being formed “on or under” another element, the term “on or under” includes both a case in which the two elements are in direct contact with each other and a case in which at least another element is disposed between the two elements (indirectly). Further, when the term “on or under” is expressed, a meaning of not only an upward direction but also a downward direction may be included based on one element.

Hereinafter, a thermoelectric module 10 according to an embodiment of the present invention will be described with reference to the drawings.

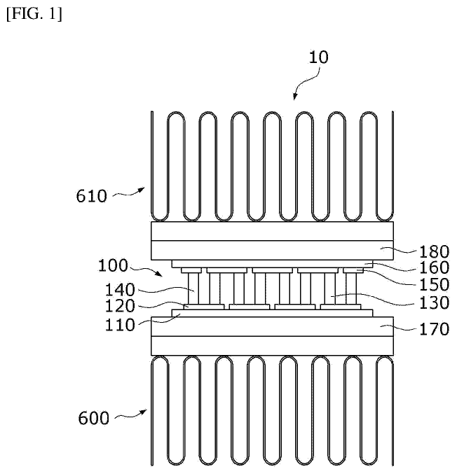

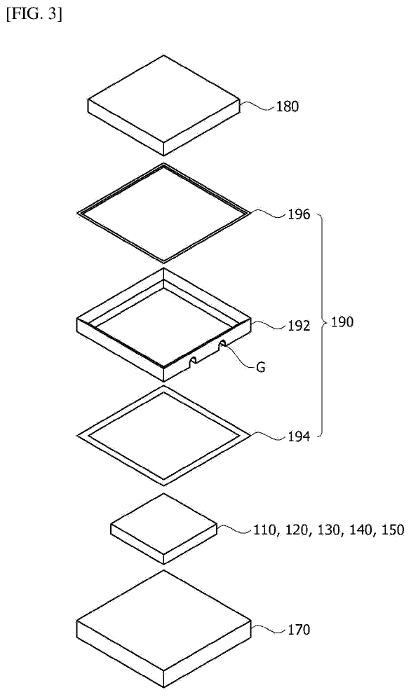

Referring to FIGS. 1 and 3, a thermoelectric element 100 includes a first substrate 170, a first resin layer 110, a plurality of first electrodes 120, a plurality of P-type thermoelectric legs 130, a plurality of N-type thermoelectric legs 140, a plurality of second electrodes 150, a second resin layer 160, and a second substrate 180.

The plurality of first electrodes 120 are disposed between the first resin layer 110 and lower surfaces of the P-type thermoelectric legs 130 and the N-type thermoelectric legs 140, and the plurality of second electrodes 150 are disposed between the second resin layer 160 and upper surfaces of the P-type thermoelectric legs 130 and the N-type thermoelectric legs 140. Accordingly, the plurality of P-type thermoelectric legs 130 and the plurality of N-type thermoelectric legs 140 are electrically connected by the plurality of first electrodes 120 and the plurality of second electrodes 150. One pair of the P-type thermoelectric leg 130 and the N-type thermoelectric leg 140 which are disposed between the first electrodes 120 and the second electrodes 150 and electrically connected to each other may form a unit cell.

One pair of the P-type thermoelectric leg 130 and the N-type thermoelectric leg 140 may be disposed on each first electrode 120, and one pair of the P-type thermoelectric leg 130 and the N-type thermoelectric leg 140 may be disposed on each second electrode 150 so that one of one pair of the P-type thermoelectric leg 130 and the N-type thermoelectric leg 140 disposed on each first electrode 120 overlaps.

Here, the P-type thermoelectric leg 130 and the N-type thermoelectric leg 140 may be bismuth-telluride (Bi—Te)-based thermoelectric legs including bismuth (Bi) and tellurium (Te) as main raw materials. The P-type thermoelectric leg 130 may be a thermoelectric leg including a bismuth-telluride (Bi—Te)-based main raw material in an amount of 99 to 99.999 wt % including at least one among antimony (Sb), nickel (Ni), aluminum (Al), copper (Cu), silver (Ag), lead (Pb), boron (B), gallium (Ga), tellurium (Te), bismuth (Bi), and indium (In), and a mixture in an amount of 0.001 to 1 wt % including Bi or Te based on 100 wt % of the total weight. For example, the main raw material may be Bi—Se—Te, and Bi or Te may be further included in an amount of 0.001 to 1 wt % of the total weight. The N-type thermoelectric leg 140 may be a thermoelectric leg including a bismuth-telluride (Bi—Te)-based main raw material in an amount of 99 to 99.999 wt % including at least one among selenium (Se), nickel (Ni), aluminum (Al), copper (Cu), silver (Ag), lead (Pb), boron (B), gallium (Ga), tellurium (Te), bismuth (Bi), and indium (In), and a mixture in an amount of 0.001 to 1 wt % including Bi or Te based on 100 wt % of the total weight. For example, the main raw material may be Bi—Sb—Te, and Bi or Te may be further included in an amount of 0.001 to 1 wt % of the total weight.

The P-type thermoelectric leg 130 and the N-type thermoelectric leg 140 may be formed in a bulk type or a stacked type. Generally, the bulk type P-type thermoelectric leg 130 or the bulk type N-type thermoelectric leg 140 may be obtained through a process of producing an ingot by heat-treating a thermoelectric material, pulverizing and sieving the ingot to obtain powder for thermoelectric legs, sintering the powder, and cutting the sintered object. In this case, the P-type thermoelectric leg 130 and the N-type thermoelectric leg 140 may be polycrystalline thermoelectric legs. For the polycrystalline thermoelectric legs, the powder for thermoelectric legs may be compressed at 100 to 200 MPa when sintered. For example, when the P-type thermoelectric leg 130 is sintered, the powder for thermoelectric legs may be sintered at 100 to 150 MPa, preferably, 110 to 140 MPa, and more preferably, 120 to 130 MPa. Further, when the N-type thermoelectric leg 130 is sintered, the powder for thermoelectric legs may be sintered at 150 to 200 MPa, preferably, 160 to 195 MPa, and more preferably, 170 to 190 MPa. Like the above, when the P-type thermoelectric leg 130 and the N-type thermoelectric leg 140 are the polycrystalline thermoelectric legs, strength of the P-type thermoelectric leg 130 and the N-type thermoelectric leg 140 may increase. Accordingly, even when the thermoelectric element 100 according to the embodiment of the present invention is applied to an application with vibration, for example, a vehicle, or the like, a problem in which cracks occur in the P-type thermoelectric leg 130 and the N-type thermoelectric leg 140 may be prevented, and durability and reliability of the thermoelectric element 100 may be improved.

In this case, one pair of the P-type thermoelectric leg 130 and the N-type thermoelectric leg 140 may have the same shape and volume or may have different shapes and volumes. For example, since electrical conduction characteristics of the P-type thermoelectric leg 130 and the N-type thermoelectric leg 140 are different, a height or cross-sectional area of the N-type thermoelectric leg 140 may be formed differently from a height or cross-sectional area of the P-type thermoelectric leg 130.

The performance of the thermoelectric element according to one embodiment of the present invention may be expressed as a thermoelectric performance index (a figure of merit, ZT). The thermoelectric performance index (ZT) may be expressed as in Equation 1.

ZT=α²·σ·T/k [Equation 1]

Here, α is the Seebeck coefficient [V/K], σ is electrical conductivity [S/m], and α2σ is a power factor (W/mK2]). Further, T is a temperature, and k is thermal conductivity [W/mK]. k may be expressed as a·cp·p, wherein a is thermal diffusivity [Cm2/S], cp is specific heat [J/gK], and ρ is density [g/cm3].

In order to obtain the thermoelectric performance index of the thermoelectric element, a Z value (V/K) is measured using a Z meter, and the thermoelectric performance index (ZT) may be calculated using the measured Z value.

Here, the plurality of first electrodes 120 disposed between the first resin layer 110 and the P-type thermoelectric legs 130 and the N-type thermoelectric legs 140, and the plurality of second electrodes 150 disposed between the second resin layer 160 and the P-type thermoelectric legs 130 and the N-type thermoelectric legs 140 may each include at least one of copper (Cu), silver (Ag), and nickel (Ni).

Further, the first resin layer 110 and the second resin layer 160 may be formed to have different sizes. For example, a volume, a thickness, or an area of one of the first resin layer 110 and the second resin layer 160 may be formed to be larger than a volume, a thickness, or an area of the other one. Accordingly, it is possible to improve the heat absorption performance or heat dissipation performance of the thermoelectric element.

In this case, the P-type thermoelectric leg 130 or the N-type thermoelectric leg 140 may have a cylindrical shape, a polygonal pillar shape, an oval pillar shape, and the like.

The first substrate 170 and the second substrate 180 may support the first resin layer 110, the plurality of first electrodes 120, the plurality of P-type thermoelectric legs 130 and the plurality of N-type thermoelectric legs 140, the plurality of second electrodes 150, the second resin layer 160, and the like. The first substrate 170 and the second substrate 180 may be made of metal. Accordingly, the first substrate 170 and the second substrate 180 may be interchanged with a first metal support and a second metal support. When the first substrate 170 and the second substrate 180 are used according to the embodiment of the present invention, since a possibility of generation of cracks is less than that of a ceramic substrate, durability may be improved, and thermal conductivity performance may be significantly high.

An area of the first substrate may be larger than an area of the first resin layer 110, and an area of the second substrate 180 may be larger than an area of the second resin layer 160. That is, the first resin layer 110 may be disposed in a region spaced apart from an edge of the first substrate 170 by a predetermined distance, and the second resin layer 160 may be disposed in a region spaced apart from an edge of the second substrate 180 by a predetermined distance.

In this case, a width length of the first substrate 170 may be larger than a width length of the second substrate 180, or a thickness of the first substrate 170 may be larger than a thickness of the second substrate 180.

In this case, the thicknesses of the first substrate 170 and the second substrate 180 may be 100 μm or more, preferably, 120 μm or more, and more preferably, 140 μm or more, and flatness may be 0.05 mm or less. When the thicknesses of the first substrate 170 and the second substrate 180 satisfy these conditions, physical strength of the thermoelectric module may increase, and even when the thermoelectric module is applied to an application in which vibration is strongly generated, such as a vehicle or the like, deformation of the substrate may be prevented.

Further, the first substrate 170 and the second substrate 180 may include copper, and more preferably, may be made of 99.9% or more of pure copper. A CTE (coefficient of thermal expansion) of the pure copper is approximately 17.6 m/mK, and is lower than approximately 19.9 m/mK which is a CTE of brass. When the first substrate 170 and the second substrate 180 are made of the pure copper, stress against a thermal change may be reduced. Accordingly, even when the thermoelectric module is applied to an application exposed to a high temperature, such as a vehicle or the like, since it is possible to prevent separation of the thermoelectric leg due to the deformation of the substrate, durability and reliability of the thermoelectric module may be increased.

The first resin layer 110 and the second resin layer 160 may be made of an epoxy resin composition including polydimethylsiloxane (PDMS) and an inorganic filler.

Here, the inorganic filler may be included in an amount of 68 to 88 vol % of the resin layer. When the inorganic filler is included in an amount less than 68 vol %, a heat conduction effect may be low, and when the inorganic filler is included in an amount greater than 88 vol %, an adhesion force between the resin layer and the metal substrate may be lowered, and the resin layer may be easily broken.

The thicknesses of the first resin layer 110 and the second resin layer 160 may be 0.02 to 0.6 mm, preferably, 0.1 to 0.6 mm, and more preferably, 0.2 to 0.6 mm, and thermal conductivity may be 1 W/mK or more, preferably, 10 W/mK or more, and more preferably, 20 W/mK or more. When the thicknesses of the first resin layer 110 and the second resin layer 160 satisfy this numerical range, even when the first resin layer 110 and the second resin layer 160 repeatedly contract and expand according to a temperature change, bonding between the first resin layer 110 and the first substrate 170 and bonding between the second resin layer 160 and the second substrate 180 may not be affected.

The inorganic filler may include at least one of aluminum oxide and nitride, and the nitride may include at least one of boron nitride and aluminum nitride. Here, the boron nitride may be a boron nitride agglomerate in which plate-shaped boron nitride is agglomerated.

When the first resin layer 110 and the second resin layer 160 include the aluminum oxide, high thermal conductive performance of the first resin layer 110 and the second resin layer 160 may be obtained.

In this case, when the first resin layer 110 and the second resin layer 160 are made of a resin composition including PDMS and the aluminum oxide, the first resin layer 110 and the second resin layer 160 may be elastic insulating layers. When the first resin layer 110 and the second resin layer 160 have elasticity, even when the contraction and the expansion are repeated according to the temperature change, a thermal shock may be alleviated, and accordingly, even when the thermoelectric element 100 is applied to an application exposed to the high temperature, such as a vehicle or the like, since it is possible to prevent separation of the thermoelectric leg, the durability and reliability of the thermoelectric element 100 may be increased.

Like the above, when the first resin layer 110 is disposed between the first substrate 170 and the plurality of first electrodes 120, heat can be transferred between the first substrate 170 and the plurality of first electrodes 120 without a separate ceramic substrate, and a separate adhesive or physical fastening means is not required due to adhesion performance of the first resin layer 110 itself. Accordingly, an overall size of the thermoelectric module may be reduced, and the durability of the thermoelectric module may be increased.

Meanwhile, the thermoelectric module according to the embodiment of the present invention further includes a sealing member 190.

The sealing member 190 may be disposed on a side surface of the first resin layer 110 and a side surface of the second resin layer 160. That is, the sealing member 190 may be disposed between the first substrate 170 and the second substrate 180, and may be disposed to surround the side surface of the first resin layer 110, the outermost side of the plurality of first electrodes 120, the outermost side of the plurality of P-type thermoelectric legs 130 and the plurality of N-type thermoelectric legs 140, the outermost side of the plurality of second electrodes 150, and the side surface of the second resin layer 160. Accordingly, the first resin layer 110, the plurality of first electrodes 120, the plurality of P-type thermoelectric legs 130, the plurality of N-type thermoelectric legs 140, the plurality of second electrodes 150, and the second resin layer may be sealed against external moisture, heat, and contamination.

Here, the sealing member 190 may include a sealing case 192 disposed to be spaced apart from the side surface of the first resin layer 110, the outermost side of the plurality of first electrodes 120, the outermost side of the plurality of P-type thermoelectric legs 130 and the plurality of N-type thermoelectric legs 140, the outermost side of the plurality of second electrodes 150, and the side surface of the second resin layer 160 by a predetermined distance, a sealing material 194 disposed between the sealing case 192 and the second substrate 180, and a sealing material 196 disposed between the sealing case 192 and the first substrate 170. Like the above, the sealing case 192 may come into contact with the first substrate 170 and the second substrate 180 through the sealing materials 194 and 196. Accordingly, when the sealing case 192 comes into direct contact with the first substrate 170 and the second substrate 180, heat conduction occurs through the sealing case 192, and accordingly, a problem in that ΔT decreases may be prevented.

Here, the sealing materials 194 and 196 may include at least one of an epoxy resin and a silicone resin, or a tape in which at least one of the epoxy resin and the silicone resin is applied on both surfaces. The sealing materials 194 and 196 may form an airtight seal between the sealing case 192 and the first substrate 170 and between the sealing case 192 and the second substrate 180, may increase a sealing effect of the first resin layer 110, the plurality of first electrodes 120, the plurality of P-type thermoelectric legs 130, the plurality of N-type thermoelectric legs 140, the plurality of second electrodes 150, and the second resin layer 160, and may be interchanged with a finishing material, a finishing layer, a waterproofing material, a waterproofing layer, and the like.

Meanwhile, guide grooves G for drawing out wires 200 and 202 connected to the electrodes may be formed in the sealing case 192. To this end, the sealing case 192 may be an injection-molded product made of plastic or the like, and may be interchanged with a sealing cover.

Although not shown, a heat insulating material may be further included to surround the sealing member 190. Alternatively, the sealing member 190 may include a heat insulating component.

Meanwhile, the thermoelectric module according to the embodiment of the present invention may be applied to an air conditioner, for example, an air conditioner for a vehicle. More specifically, the thermoelectric module according to the embodiment of the present invention may be embedded in a ventilation seat of a vehicle.

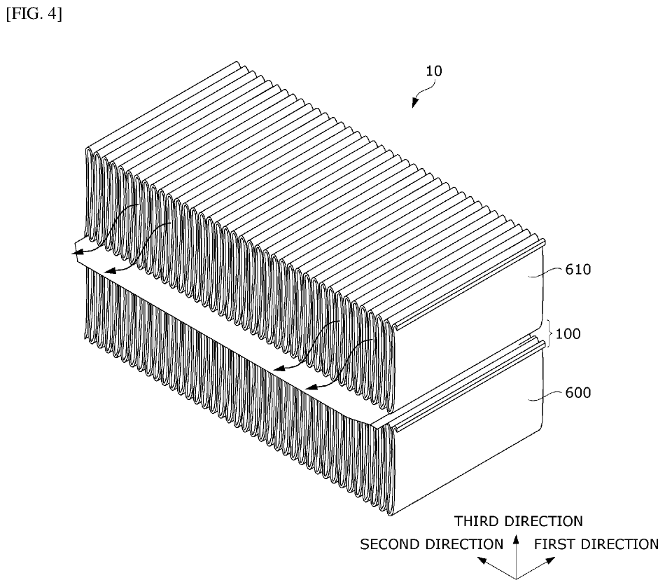

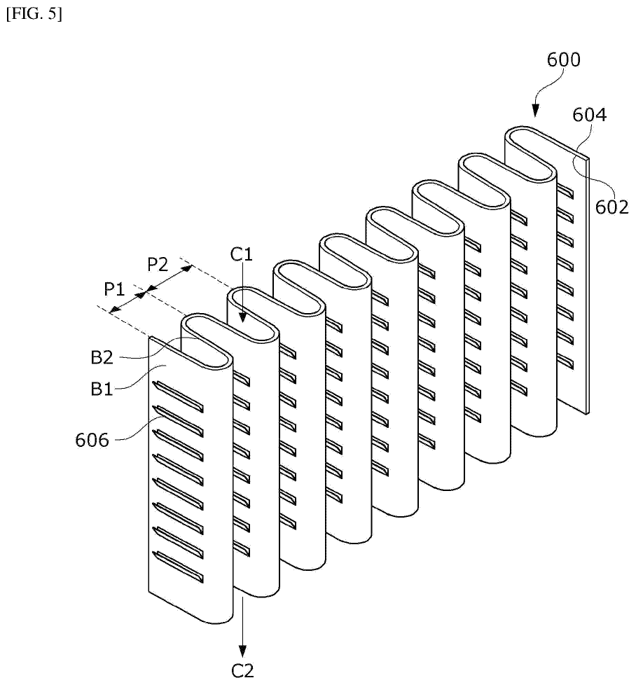

FIG. 4 is a perspective view of the thermoelectric module according to one embodiment of the present invention, and FIGS. 5 to 7 illustrate a heat transfer member included in the thermoelectric module according to one embodiment of the present invention.

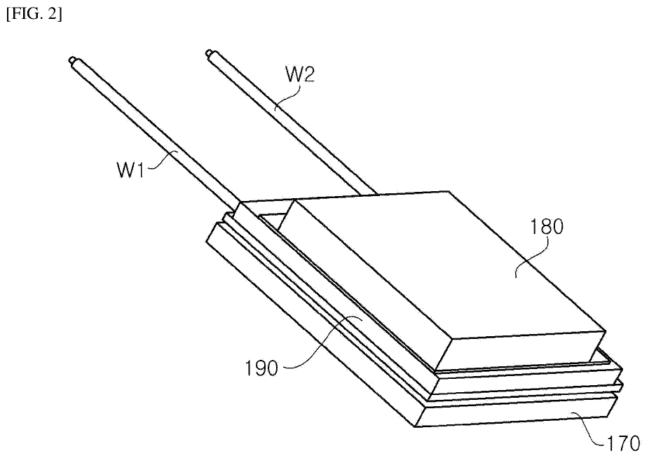

Referring to FIG. 4, a thermoelectric module 1000 includes a thermoelectric element 100, a first heat transfer member 600, and a second heat transfer member 610. Here, the thermoelectric element 100 may be the thermoelectric element according to FIGS. 1 to 4.

According to the embodiment of the present invention, the first substrate 170 of the thermoelectric element 100 is disposed on the first heat transfer member 600, and the second heat transfer member 610 is disposed on the second substrate 180 of the thermoelectric element 100.

When the thermoelectric module 1000 is applied to an apparatus which generates hot or cold air, at least one of the first substrate 170 and the second substrate 180 may be a low-temperature part, and the other may be a high-temperature part.

According to the embodiment of the present invention, when the first substrate 170 becomes a high-temperature part, each of the first heat transfer member 600 and the second heat transfer member may form a plurality of air flow paths. In this case, a surface area of the first heat transfer member 600 may be larger than a surface area of the second heat transfer member. In this case, a ratio of the surface area of the first heat transfer member to the surface area of the second heat transfer member may be 1.1 to 5, preferably, 2 to 4, and more preferably, 2.5 to 3.5.

Hereinafter, the present invention will be described in more detail through the thermoelectric modules according to the embodiments.

Table 1 below is a table in which a temperature of the second heat exchange member is measured according to the ratio of the surface area of the first heat exchange member to the surface area of the second heat exchange member.

The thermoelectric modules according to Experimental Examples have the same structure as in FIG. 4, and include a thermoelectric element 100, a first heat transfer member 600, and a second heat transfer member 610.

However, Experimental Example 1 was tested so that the surface area ratio of the first heat exchange member and the second heat exchange member was 1:1, Experimental Example 2 was tested so that the surface area ratio of the first heat exchange member and the second heat exchange member was 1:1.5, Experimental Example 3 was tested so that the surface area ratio of the first heat exchange member and the second heat exchange member was 1:3, and Experimental Example 4 was tested so that the surface area ratio of the first heat exchange member and the second heat exchange member was 1:5.

TABLE 1

| Experimental Example | Temperature |
|---|---|
| Experimental Example 1 | 61° C. |
| Experimental Example 2 | 153.8° C. |
| Experimental Example 3 | 232.3° C. |
| Experimental Example 4 | 235.6° C. |

Referring to Table 1, it can be seen that heat exchange performance increases as the surface area of the second heat exchange member increases compared to the first heat exchange member, and thus the temperature of the second heat exchange member, that is, the temperature of the high-temperature part increases. However, when the surface area of the second heat exchange member increases three times or more compared to the first heat exchange member, the heat exchange performance does not increase more in the second heat exchange member.

Even when the first substrate 170 according to another embodiment of the present invention becomes a low-temperature part, the surface area of the first heat transfer member is formed to be larger than the surface area of the second heat transfer member in the same manner to increase a heat exchange time of the low-temperature part, and thus heat absorption performance may be further improved.

In this case, the ratio of the surface area of the first heat transfer member to the surface area of the second heat transfer member may also be 1.1 to 5, preferably, 2 to 4, and more preferably, 2.5 to 3.5. Also in this case, when the surface area of the first heat exchange member increases three times or more compared to the second heat exchange member, the heat exchange performance does not increase more in the first heat exchange member.

Since this thermoelectric module according to the present invention may lower a cooling temperature of the low-temperature part to a lower temperature by increasing the heat exchange area and heat exchange time of the heat exchange member installed in the low-temperature part, when the thermoelectric module is applied to a cooling and heating device, cooling performance of the thermoelectric module may be improved, and as the heat exchange area and heat exchange time of the first heat exchange member of the low-temperature part are increased compared to the second heat exchange member of the high-temperature part, the performance of the thermoelectric module may be further improved by improving the cooling efficiency of the low-temperature part while reducing heat interference due to the heat generation of the high-temperature part.

Here, the first heat transfer member 600 may have the structure shown in FIGS. 5 to 7. Only the first heat transfer member 600 is described as an example for convenience of description, but the present invention is not limited thereto, and the second heat transfer member 610 may have the same structure as the first heat transfer member 600.

Referring to FIGS. 5 to 7, the first heat transfer member 600 may include a folding unit 601 regularly folded to form an air flow path C1, which is a movement path of uniform air, on a plate-shaped base substrate of a first flat surface 602 and a second flat surface 604 which is a surface opposite the first flat surface 602 so as to perform surface contact with air.

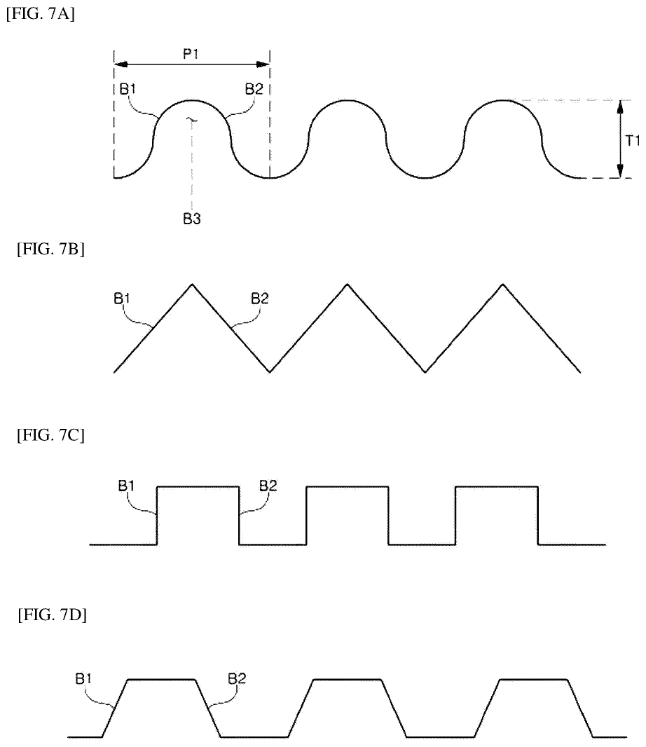

As shown in FIGS. 5 to 7, this folding unit 601 may also be implemented in a manner of forming in a structure in which the base substrate is folded so that curvature patterns having constant pitches P1 and P2 and a height T1 are formed, that is, in a folding structure, and this folding unit 601 may be formed in various modifications as shown in FIG. 7 as well as the structure shown in FIG. 5. That is, the first heat transfer member 600 according to the embodiment of the present invention may be implemented in a structure provided with two flat surfaces which come into surface contact with air and formed with a flow path pattern for maximizing a contact surface area. In the structure shown in FIG. 5, when air is introduced in a direction of the flow path C1 of an introduction portion, since the above-described first flat surface 602 and second flat surface 604 opposite the first flat surface 602 may uniformly come into contact with the air and move to proceed in a direction of an end C2 of the flow path, it is possible to induce contact with much more air in the same space than the contact surface with a simple plate shape, and thus effect of heat absorption or heating will be further improved. Here, the direction from C1 to C2 may be a first direction of FIG. 4 or a direction opposite the first direction.

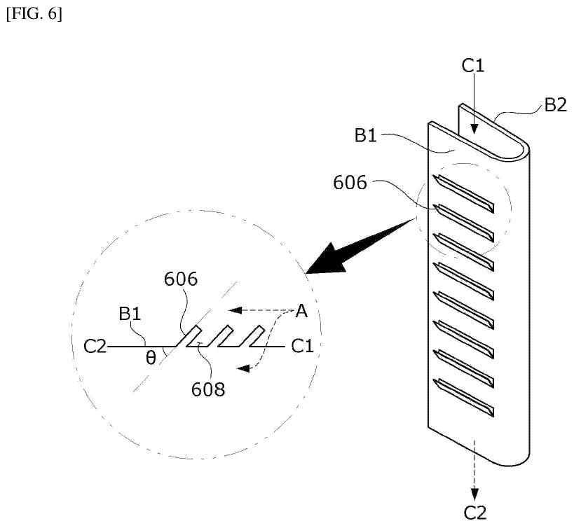

Specifically, in order to further increase a contact area of the air, the first heat transfer member 600 according to the embodiment of the present invention may include a protruding resistance pattern 606 on the surface of the base substrate, as shown in FIGS. 5 and 6. The resistance pattern 606 may be formed on each of a first curved surface B1 and a second curved surface B2 in consideration of a unit flow path pattern.

Further, as shown in a partially enlarged view in FIG. 6, the resistance pattern 606 is formed of a protruding structure inclined to have a predetermined inclination angle θ in the direction in which the air enters to further increase the contact area or contact efficiency by maximizing friction with the air. Further, a groove 608 (hereinafter referred to as a ‘flow groove 608’) may be formed on the surface of the base substrate in front of the resistance pattern 606 so that some of the air which comes into contact with the resistance pattern 606 may pass through front and rear surfaces of the base substrate to further increase the frequency or area of contact. In addition, in the example shown in FIG. 6, the resistance pattern was formed in a structure disposed to maximize resistance in a flow direction of air, but it is not limited to this shape, and a direction of the resistance pattern which protrudes so that the degree of the resistance may be adjusted according to a design of the resistance may be designed to be reversed. In FIG. 6, the resistance pattern 606 is implemented to be formed on an outer surface of a heat sink, but on the contrary, the resistance pattern 606 may also be modified in a structure formed on an inner surface of the heat sink.

For example, referring to FIG. 7, (a) a pattern having a curvature at a constant pitch P1 may be repeatedly formed, (b) the unit pattern of the folding unit 601 may be implemented in a repeating structure of a pattern structure having an attachment, or as shown in (c) and (d), the unit pattern may be variously changed to have a polygonal cross-section. In the above-described folding unit 601, the resistance pattern described above in FIG. 6 may be provided on surfaces B1 and B2 of the pattern.

As shown in FIG. 7, although the folding unit 601 is formed to have a constant period in a structure having a constant pitch, unlike this, the pitch of the unit pattern may not be uniform, and the period of the pattern may also be modified to be non-uniform. Further, a height T1 of each unit pattern may also be non-uniformly modified.

Hereinafter, a modified example for increasing a surface area of the air flow path C1 of the first heat transfer member 600 included in the thermoelectric module according to the embodiment of the present invention will be described.

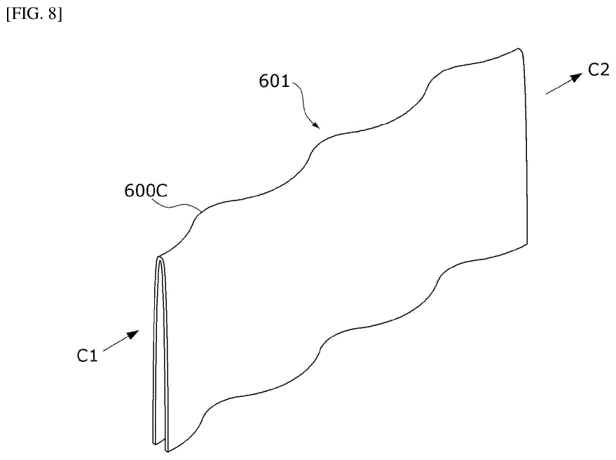

FIGS. 8 to 10 are modified examples of the first heat transfer member 600 included in the thermoelectric module according to one embodiment of the present invention. Here, as shown in FIGS. 5 to 7, the first heat transfer member 600 may include a plurality of folding units 601 in which a plate-shaped base substrate is regularly folded to have a predetermined interval.

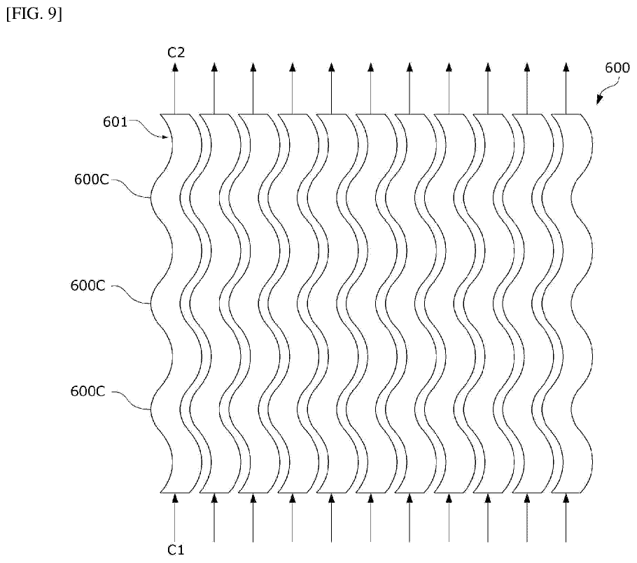

Each folding unit 601 may include at least one bent portion 600C. Referring to FIG. 9, the folding unit 601 may include a plurality of bent portions 600C. In this case, the plurality of bent portions 600C may be repeatedly disposed in the direction of the air flow path C1, that is, in a direction parallel to the first substrate 170.

In this case, referring to FIG. 9, the folding unit 601 includes the plurality of bent portions 600C, each bent portion 600C may be formed to have a U-shaped cross section, the plurality of bent portions 600C may be formed in the same shape, and the plurality of bent portions 600C may be repeatedly disposed along the direction of the air flow path C1.

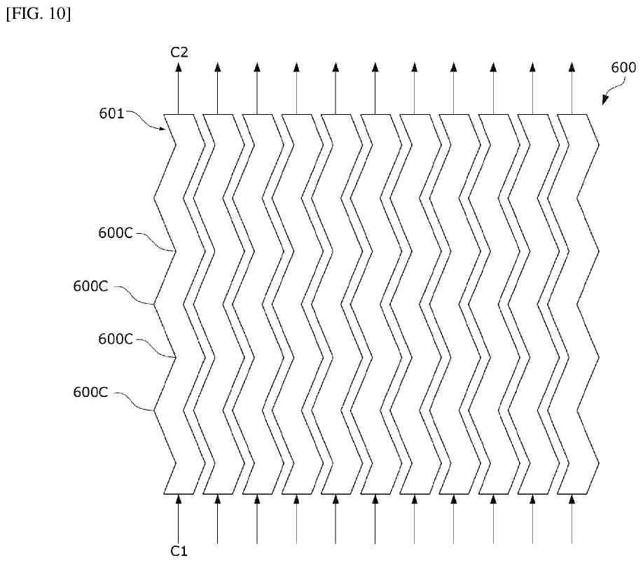

Meanwhile, referring to FIG. 10, the folding unit 601 includes a plurality of bent portions 600C, each bent portion 600C may be formed to have a V-shaped cross section, the plurality of bent portions 600C may be formed in the same shape, and the plurality of bent portions 600C may be repeatedly disposed along the direction of the air flow path C1.

Although not shown in the drawings, the plurality of bent portions 600C may be formed to have a polygonal-shaped cross-section. Further, the folding unit 601 may include one bent portion 600C, and thus may have a convex or concave shape in a central portion compared to edges. Meanwhile, the folding unit 601 may form a curve while being bent in one direction without including the bent portion, and the curved shape may be non-uniformly modified.

In this case, although not shown in the drawings, the second heat transfer member 610 may include a plurality of folding units in which a plate-shaped base substrate is regularly folded to have a predetermined interval like the structure of the first heat transfer member 600 shown in FIG. 5, and the plurality of folding units may include at least one bent portion or may be bent to form a curve. However, the folding unit 601 of the first heat transfer member 600 may have a greater number of bent portions or a greater bending angle than the folding unit of the second heat transfer member 610. This is to form an air flow path surface area of the first heat transfer member 600 larger than an air flow path surface area of the second heat transfer member 610.

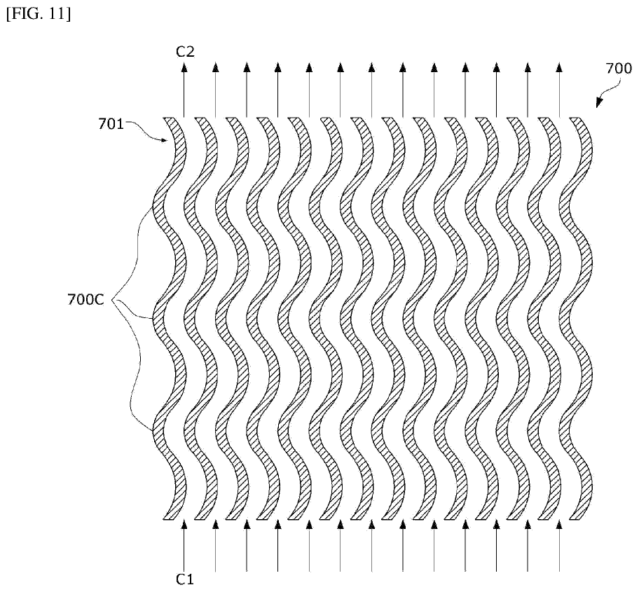

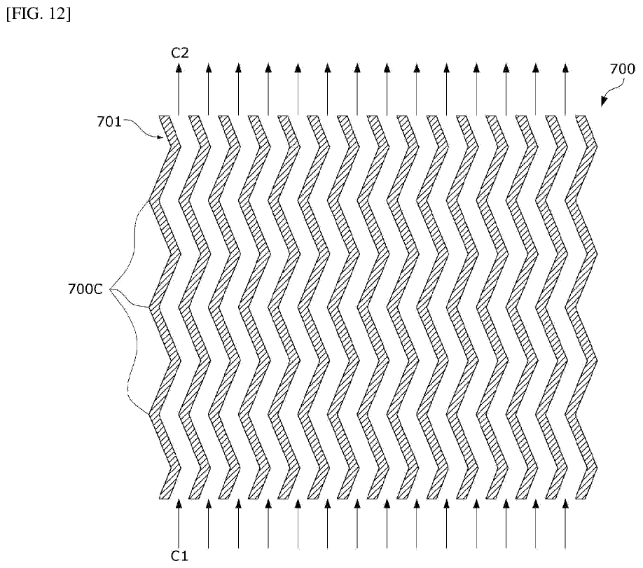

FIGS. 11 and 12 are modified examples of a first heat transfer member included in a thermoelectric module according to another embodiment of the present invention. Here, in a first heat transfer member 700, a plurality of plate-shaped base substrates 701 may be disposed to be spaced apart from each other, and an air flow path is formed between the plurality of base substrates 701.

Referring to FIG. 11, the plate-shaped base substrate 701 may include a plurality of bent portions 700C. In this case, each bent portion 700C may be formed to have a U-shaped cross section, the plurality of bent portions 700C may be formed in the same shape, and the plurality of bent portions 700C may be repeatedly disposed along the direction of the air flow path C1.

Meanwhile, referring to FIG. 12, the plate-shaped base substrate 701 includes a plurality of bent portions 700C, each bent portion 700C may be formed to have a V-shaped cross section, the plurality of bent portions 700C may be formed in the same shape, and the plurality of bent portions 700C may be repeatedly disposed along the direction of the air flow path C1.

Although not shown in the drawings, the plurality of bent portions 700C may be formed to have a polygonal-shaped cross-section. Further, the plate-shaped base substrate 701 may include one bent portion 700C, and thus may have a convex or concave shape in a central portion compared to edges. Meanwhile, the plate-shaped base substrate 701 may form a curve while being bent in one direction without including the bent portion, and the curved shape may be non-uniformly modified.

In this case, although not shown in the drawings, in the second heat transfer member 610, the plurality of plate-shaped base substrates may be disposed to be spaced apart from each other like the structure of the first heat transfer member 700 shown in FIGS. 11 and 12, and the plurality of plate-shaped base substrates may include at least one bent portion or may be bent to form a curve. However, the plate-shaped base substrate 701 of the first heat transfer member 700 may have a greater number of bent portions or a greater bending angle than the plate-shaped base substrate of the second heat transfer member 610. This is to form an air flow path surface area of the first heat transfer member 70 larger than an air flow path surface area of the second heat transfer member.

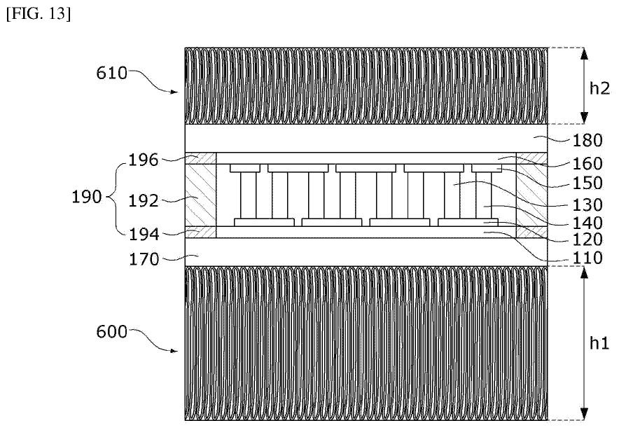

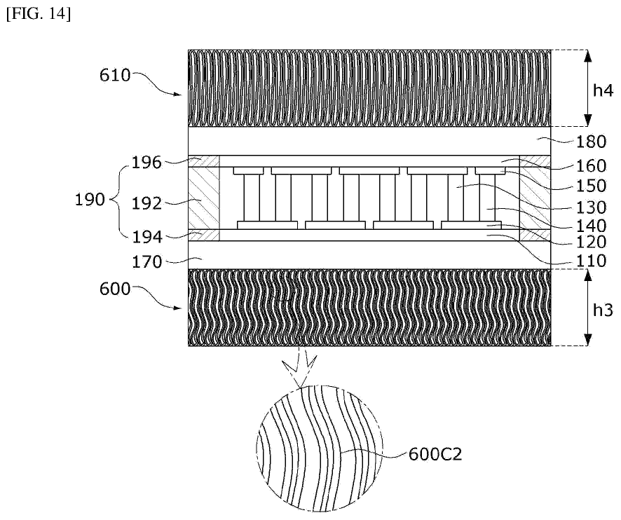

FIGS. 13 and 14 are modified examples of a first heat transfer member included in a thermoelectric module according to still another embodiment of the present invention. Here, each of the first heat transfer member 600 and the second heat transfer member 610 may include a plurality of folding units in which a plate-shaped base substrate is regularly folded to have a predetermined interval as shown in FIGS. 5 to 7. Meanwhile, although not shown in the drawings, the embodiment is also applicable to a structure in which the first heat transfer member and the second heat transfer member are implemented with the plurality of plate-shaped base substrates spaced apart from each other.

Referring to FIG. 13, a height h1 of the first heat transfer member 600 may be formed greater than a height h2 of the second heat transfer member 610. Here, a ratio of the height h1 of the first heat transfer member 600 to the height h2 of the second heat transfer member 610 may be 1.1 to 5, preferably, 2 to 4, and more preferably, 2.5 to 3.5. In this case, the surface area of the first heat transfer member 600 may increase in a direction perpendicular to the first substrate 170 and the second substrate 180, that is, in a third direction, more than the surface area of the second heat transfer member 610

Referring to FIG. 14, a height h3 of the first heat transfer member 600 and a height h of the second heat transfer member 610 may be fixed to be the same, and the surface areas of the heat transfer members may be differently applied.

In this case, the plate-shaped base substrate or the folding unit included in the first heat transfer member 600 may include a plurality of bent portions 600C2, and the plurality of bent portions 600C2 may be repeatedly arranged in a direction perpendicular to the first substrate 170, that is, in the third direction.

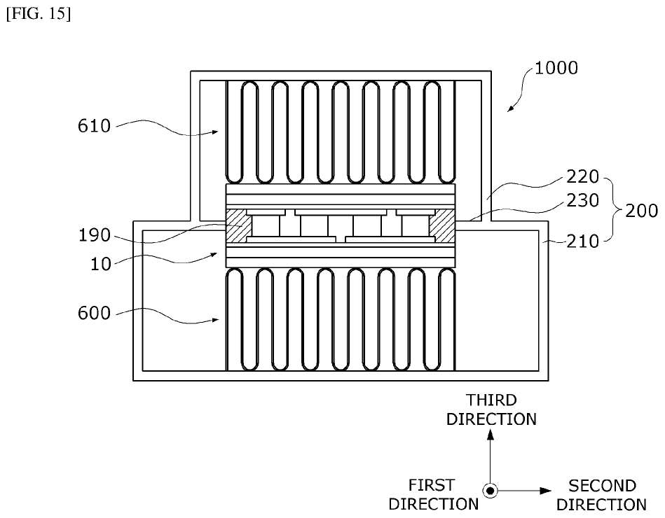

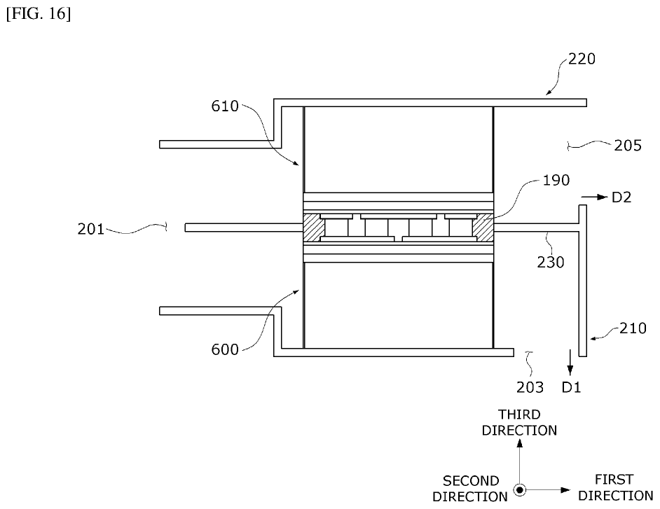

Hereinafter, a cooling and heating device according to one embodiment of the present invention will be described with reference to FIGS. 15 and 16. The cooling and heating device according to the embodiment includes the thermoelectric module shown in FIG. 1. Accordingly, in the embodiment, the same reference numerals are granted to the thermoelectric module shown in FIG. 1, and repeated descriptions will be omitted.

FIG. 15 is a cross-sectional view of the cooling and heating device according to one embodiment of the present invention, and FIG. 16 is a side cross-sectional view of the cooling and heating device according to one embodiment of the present invention.

Here, a direction coinciding with a flow of air introduced into the cooling and heating device is referred to as a first direction, a direction parallel to the first substrate 170 and the second substrate 180 and orthogonal to the first direction is referred to as a second direction, and a direction from the first substrate 170 toward the second substrate 180 is referred to as a third direction.

Referring to FIGS. 15 and 16, a cooling and heating device 1000 includes a housing 200 including a first housing 210 and a second housing 220, a fan (not shown) which circulates air introduced into the housing 200, and a thermoelectric module 10 accommodated in the housing 200, and configured cool a part of the air ventilated by the fan (not shown) and heat the remaining part.

The thermoelectric module 10 includes the first heat transfer member 410 disposed in the first housing 210, the second heat transfer member 420 disposed in the second housing 220, and a thermoelectric element disposed between the first heat transfer member 410 and the second heat transfer member 420.

The thermoelectric module 10 is accommodated in an inner space of the housing 200. In this case, the housing 200 may be made of a synthetic resin, for example, plastic. The housing 200 may include the first housing 210 and the second housing 220. In this case, the first heat transfer member 600 may be disposed in the first housing 210, and the second heat transfer member 610 may be disposed in the second housing 220.

According to the embodiment of the present invention, a volume of an inner space of the first housing 210 may be larger than a volume of an inner space of the second housing 220. A ratio of the volume of the inner space of the first housing 210 to the volume of the inner space of the second housing 220 may be 1.1 to 5, preferably, 1.1 to 3, and more preferably, 1.5 to 2.5.

Referring to FIG. 16, the housing 200 may include an introduction port 201 through which air is introduced, a ventilation port 203 through which the introduced air is discharged from the housing 200 through the first heat transfer member 600, and a discharge port 205 through which the introduced air is discharged from the housing 200 through the second heat transfer member 610.

In this case, the ventilation port 203 may be disposed at one side of the first housing 210, and the discharge port 205 may be disposed at another side of the second housing 220. That is, the ventilation port 203 and the discharge port 205 are isolated by an isolation member 230, and the air passing through the first heat transfer member 600 and the second heat transfer member 610 may pass through the ventilation port 203 or the discharge port 205 without being mixed.

First, air may be introduced into the housing 200 from the fan (not shown) through the introduction port 201 and may proceed toward the thermoelectric module 10. The first heat transfer member 600 and the second heat transfer member 610 included in the thermoelectric module 10 may be disposed in a direction in which an air flow path is directed from the fan toward the ventilation port 203. When the cooling and heating device 1000 is used as a cooling device, the first substrate of the thermoelectric module 10 becomes a low-temperature part to cool the first heat transfer member 600, and the second substrate becomes a high-temperature part to heat the second heat transfer member 610. Accordingly, some of the air circulated by the fan (not shown) and proceeding toward the thermoelectric module 10 is cooled by passing through the first heat transfer member 600, and the remaining air may be heated by passing through the second heat transfer member 610. In this case, the cooled air may be ventilated through the ventilation port 203, and the heated air may be discharged through the discharge port 205. On the contrary, when the cooling and heating device 1000 is used as a heating device, the first substrate of the thermoelectric module 10 becomes a high-temperature part and thus the first heat transfer member 600 is heated, and the second substrate becomes a low-temperature part and thus the second heat transfer member 610 is cooled. Accordingly, some of the air circulated by the fan and proceeding toward the thermoelectric module 400 may be heated by passing through the first heat transfer member 410, and the remaining air may be cooled by passing through the second heat transfer member 610. In this case, the heated air may be ventilated through the ventilation port 203, and the cooled air may be discharged through the discharge port 205.

That is, the air passing through the first heat transfer member 600 after being circulated by the fan (not shown) may be ventilated from the ventilation port 203 and used for cooling or heating. Further, the air passing through the second heat transfer member 420 may be discharged from the discharge port 205 and discarded to the outside.

More specifically, a direction D1 in which air is discharged through the ventilation port 203 and a direction D2 in which air is discharged through the discharge port 205 may be different from each other. Accordingly, the air that is cooled or heated, and discharged to the ventilation port 203 to realize performance of the cooling and heating device 1000 and the air discharged to an exhaust pipe 204 to be discarded after being used for cooling or heating the air discharged to the ventilation port 203 are not mixed, and cooling or heating performance may be improved.

To this end, the ventilation port 203 may be disposed on a lower surface of the first housing 210, and the discharge port 205 may be disposed on a side surface of the second housing 220 which is different from the lower surface. In this case, the side surface is a surface disposed in a direction in which the air cooled and heated by the thermoelectric module 10 after being circulated by the fan (not shown) passes through the first heat transfer member 600 and the second heat transfer member 610, and then proceeds. Further, the lower surface may be a surface perpendicular to the side surface.

Like the above, when the directions of the introduction port 201, the ventilation port 203, and the discharge port 205 are different from each other, since a problem in that the air ventilated through the ventilation port 203 or the air discharged through the discharge port 205 flows back into the introduction port 201 may be minimized, it is possible to increase the cooling and heating performance of the cooling and heating device.

Although not shown in the drawings, any one or more of the introduction port 201, the ventilation port 203, and the discharge port 205 may selectively further connect a separate air flow path for additionally controlling an introduction direction, a ventilation direction, or a discharge direction of the air. In this case, a final introduction direction, a final ventilation direction, and a final discharge direction of the air flow path selectively connected to the introduction port 201, the ventilation port 203, and the discharge port 205 may be different from each other.

The housing 200 may further include the isolation member 230 disposed between the first housing 210 and the second housing 220 to isolate the first housing 210 and the second housing 220 from each other. The isolation member 230 may be made of a synthetic resin, for example, plastic, and may be integrally formed with the housing 200.

Here, the isolation member 230 is disposed in the direction parallel to the first substrate 170 and the second substrate 180. In this case, the isolation member 230 may be located between the first and second substrates 170 and 180. Further, a sealing member 190 may be disposed between the isolation member 230 and the thermoelectric module 400. The sealing member 190 forms an airtight seal between the first housing 210 and the second housing 220 to block introduction of the air heated in the second housing 220 into the first housing 210.

The sealing member 190 may serve to form an airtight seal between the isolation member 230 and the thermoelectric module 10, may increase a sealing effect of the first electrodes 120, the P-type thermoelectric legs 130, the N-type thermoelectric legs 140, and the second electrodes 150, and may be interchanged with a finishing material, a finishing layer, a waterproofing material, a waterproofing layer, and the like. However, the above description of the sealing member 190 is only an example, and the sealing member 190 may be modified into various forms. Although not shown, an insulating material may be further included to surround the sealing member 190. Alternatively, the sealing member 190 may also include a heat insulating component.

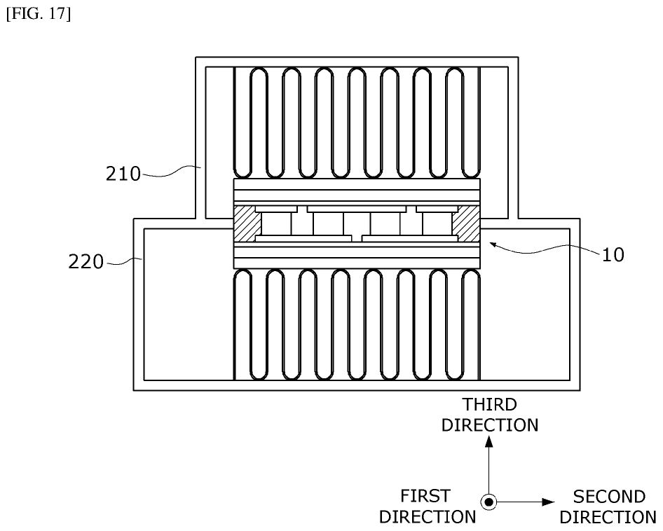

Hereinafter, various modified examples of the housing included in the cooling and heating device according to one embodiment of the present invention will be described with reference to FIGS. 17 to 20.

FIGS. 17 to 20 are various modified examples of the housing included in the cooling and heating device according to one embodiment of the present invention.

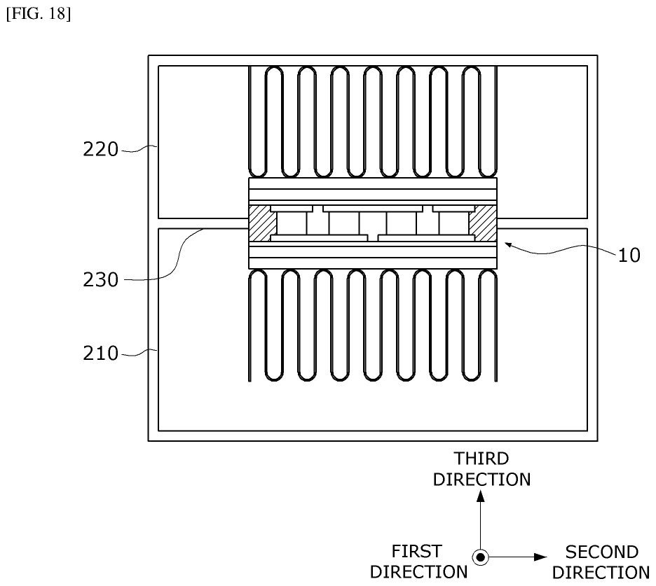

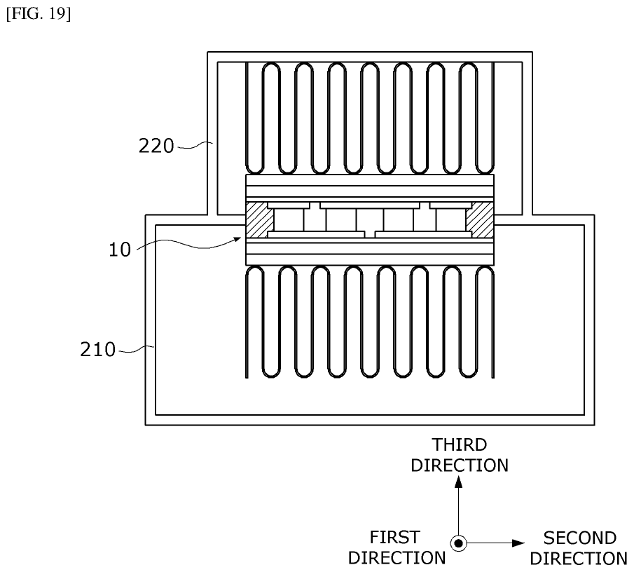

An inner space of a first housing 210 may have a larger volume than that of a second housing 220 in various shapes. Referring to FIG. 17, an inner space of a first housing 210 may be formed to be larger than an inner space of a second housing 220 in the second direction. Referring to FIG. 18, an inner space of a first housing 210 may be formed to be larger than an inner space of a second housing 220 in the third direction. Referring to FIG. 19, an inner space of a first housing 210 may be formed to be larger than an inner space of a second housing 220 in the second and third directions. More specifically, a ratio of a volume of the inner space of the first housing 210 to a volume of the inner space of the second housing 220 may be 1.1 to 5, preferably, 1.1 to 3, and more preferably, 1.5 to 2.5.

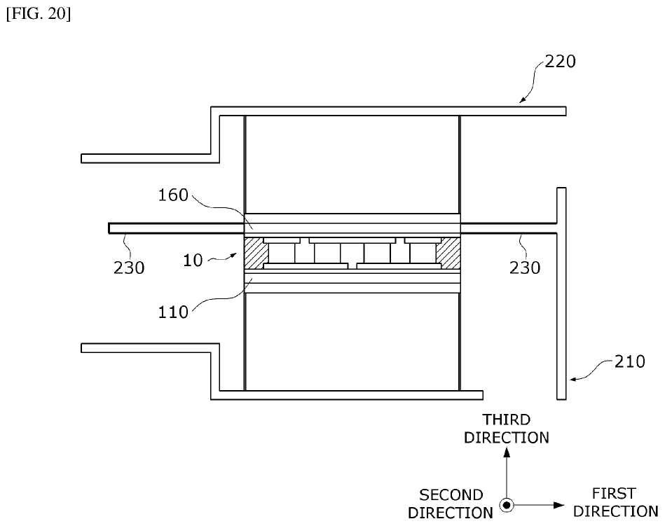

The isolation member 230 may be disposed parallel to the first substrate 170 and the second substrate 180. In this case, the isolation member 230 may be connected to any one selected from the first substrate 170 and the second substrate 180. Specifically, as shown in FIG. 20, when the isolation member 230 is connected to the second substrate 180, it is advantageous to secure the inner space of the first housing 210 to be larger than the inner space of the second housing 220. In this case, a separation distance between the isolation member 230 and the selected one of the first substrate 170 and the second substrate 180 may be 0 to 1 mm or less.

Hereinafter, the present invention will be described in more detail through the cooling and heating devices according to Experimental Examples.

Table 2 below is a table in which power consumption according to the ratio of the inner space volume of the first housing and the inner space volume of the second housing is measured.

All of the cooling and heating devices according to Experimental Examples each include a housing including a first housing and a second housing, a first heat transfer member disposed in the first housing, a second heat transfer member disposed in the second housing, and a thermoelectric element disposed between the first heat transfer member and the second heat transfer member.

However, Comparative Example 1 was tested so that the ratio of the inner space volume of the first housing to the inner space volume of the second housing was 1:1, Experimental Example 1 was tested so that the volume ratio was 1.5:1, Experimental Example 2 was tested so that the volume ratio was 2:1, and Experimental Example 3 was tested so that the volume ratio was 3:1.

TABLE 2

| Experimental Example | Power consumption |
|---|---|
| Comparative Example 1 | 14.58 W |
| Experimental Example 1 | 12.22 W |
| Experimental Example 2 | 11.10 W |
| Experimental Example 3 | 11.15 W |

Referring to Table 2, it was confirmed that the power consumption gradually decreases and then increases again as the ratio of the inner space volume of the first housing to the inner space volume ratio of the second housing increases. According to the experiment, it can be seen that the power consumption is most effectively reduced when the ratio of the inner space volume of the first housing and the inner space volume of the second housing is 2:1.

Table 2 below is a table in which the temperature of the second heat transfer member (high-temperature part) according to the separation distance between the isolation member and the first substrate or the second substrate is measured when the cooling and heating device is driven.

All of the cooling and heating devices according to Experimental Examples each include a housing including a first housing and a second housing, a first heat transfer member disposed in the first housing, a second heat transfer member disposed in the second housing, and a thermoelectric element disposed between the first heat transfer member and the second heat transfer member.

However, Comparative Example 2 did not include an isolation member which separates the first housing and the second housing, and Experimental Examples 4 to 6 each included an isolation member between the first housing and the second housing like the structure in FIG. 13.

However, in Experimental Examples 4 to 6, separation distances between the isolation member and the first or second substrate were different. Experimental Example 4 was tested so that the separation distance between the isolation member and the first or second substrate was 0 mm, Experimental Example 5 was tested so that the separation distance was 1 mm, and Experimental Example 6 was tested so that the separation distance was 2 mm.

TABLE 3

| | Temperature of second |
|---|---|
| Experimental Example | heat transfer member |
| Comparative Example 2 | 48.22° C. |
| Experimental Example 4 | 46.48° C. |
| Experimental Example 5 | 46.22° C. |
| Experimental Example 6 | 48.13° C. |

Referring to Table 3, in Experimental Example 4 and Experimental Example 5, the temperature of the second heat transfer member (high-temperature part) dropped by 1° C. to 2° C. compared to Comparative Example 2 without the isolation member, but in Experimental Example 6, a temperature difference of the second heat transfer member (high-temperature part) compared to that of Comparative Example 2 was measured to be less than 0.1° C. That is, when the separation distance between the isolation member and the first or second substrate is 0 to 1 mm, the temperature of the high-temperature part of the cooling and heating device is effectively reduced, and when the separation distance exceeds 2 mm, it can be seen that an effect of the isolation member is inadequate.

The cooling and heating device according to the embodiment of the present invention may lower overall temperatures of the low-temperature part and the high-temperature part of the cooling and heating device by increasing a flow rate of the low-temperature part and decreasing a flow velocity of the low-temperature part to lower the temperature of the low-temperature part, and accordingly, power consumption may be reduced.

Like the above, the thermoelectric module according to the embodiment of the present invention may be applied to the cooling and heating device. Here, the cooling and heating device may be a device including at least one of a cooling function and a heating function, and may be an air conditioning device or a ventilation device.

The thermoelectric module according to the embodiment of the present invention may be variously applied to applications which require at least one of a cooling function and a heating function, such as furniture, home appliances, vehicles, chairs, beds, clothes, bags, and the like.

Although preferable embodiments of the present invention are described above, those skilled in the art may variously modify and change the present invention within a range not departing from the spirit and area of the present invention disclosed in the claims which will be described below.

1. A thermoelectric module comprising:
a housing;
a thermoelectric element accommodated in the housing; and
a sealing member disposed on a peripheral of the thermoelectric element;
wherein the thermoelectric element includes a first substrate, a plurality of first electrodes disposed on the first substrate, a plurality of thermoelectric legs disposed on the plurality of first electrodes, a plurality of second electrodes disposed on the plurality of thermoelectric legs, and a second substrate disposed on the second electrodes, and
the sealing member comes into contact with a side surface of at least one of the first electrodes, the second electrodes, and the plurality of thermoelectric legs.

2. The thermoelectric module of claim 1, further comprising a heat transfer member disposed on the thermoelectric element and including a plurality of grooves,
wherein the heat transfer member includes a first heat transfer member disposed under the first substrate, and a second heat transfer member disposed on the second substrate.

3. The thermoelectric module of claim 2, wherein:
the heat transfer member includes a plurality of protruding patterns respectively disposed adjacent to the grooves thereof; and
the protruding patterns are disposed to have a constant inclination angle with respect to a direction in which air enters an air flow path.

4. The thermoelectric module of claim 2, wherein:
the first substrate is a low-temperature part;
the second substrate is a high-temperature part;
a surface area of the first heat transfer member is larger than a surface area of the second heat transfer member; and
a ratio of the surface area of the first heat transfer member to the surface area of the second heat transfer member is 1.1 to 5.

5. The thermoelectric module of claim 2, wherein:
at least one of the first heat transfer member and the second heat transfer member is disposed so that a plurality of plate-shaped base substrates are spaced apart from each other;
the plurality of plate-shaped base substrates include at least one bent portion; and
the number of bent portions included in the first heat transfer member is greater than the number of bent portions included in the second heat transfer member.

6. The thermoelectric module of claim 2, wherein:
at least one of the first heat transfer member and the second heat transfer member includes a plurality of folding units in which a plate-shaped base substrate is regularly folded to have a predetermined interval;
the plurality of folding units include at least one bent portion; and
the number of bent portions included in the first heat transfer member is greater than the number of bent portions included in the second heat transfer member.

7. The thermoelectric module of claim 5, wherein:
the bent portion is plural; and
the plurality of bent portions are repeatedly disposed along an air flow path direction.

8. The thermoelectric module of claim 5, wherein:
the bent portion is plural; and
the plurality of bent portions are repeatedly disposed along a direction from the first substrate to the first heat transfer member or a direction from the second substrate to the second heat transfer member.

9. The thermoelectric module of claim 1, wherein:
the housing includes a first housing and a second housing;
a first heat transfer member is disposed in the first housing;
a second heat transfer member is disposed in the second housing;
a volume of an inner space of the first housing is larger than a volume of an inner space of the second housing; and
a ratio of the volume of the inner space of the first housing to the volume of the inner space of the second housing is 1.1 to 3.

10. The thermoelectric module of claim 9, wherein:
the housing further includes an isolation member disposed between the first housing and the second housing to isolate the first housing and the second housing from each other; and
the isolation member is connected to one of the first substrate and the second substrate, or disposed between the first substrate and the second substrate.

11. The thermoelectric module of claim 10, wherein the housing includes an introduction port through which air is introduced, a ventilation port through which the air introduced through the introduction port is discharged from the housing through the first heat transfer member, and a discharge port through which the air introduced through the introduction port is discharged from the housing through the second heat transfer member.

12. The thermoelectric module of claim 11, wherein:
the ventilation port is disposed at the first housing;
the discharge port is disposed at the second housing; and
the ventilation port and the discharge port are isolated by the isolation member.

13. The thermoelectric module of claim 12, wherein a direction in which air is discharged through the ventilation port and a direction in which air is discharged through the discharge port are different from each other.

14. The thermoelectric module of claim 12, wherein the ventilation port is disposed on a lower surface of the first housing, and the discharge port is disposed on a side surface of the second housing.

15. The thermoelectric module of claim 10, wherein the sealing member is disposed between the isolation member and the thermoelectric element.

16. The thermoelectric module of claim 15, wherein the isolation member is connected to the sealing member.

17. The thermoelectric module of claim 16, wherein the sealing member includes a heat insulating component.

18. The thermoelectric module of claim 2, wherein:
the first substrate is a low-temperature part;
the second substrate is a high-temperature part;
a height of the first heat transfer member is greater than a height of the second heat transfer member.

19. The thermoelectric module of claim 6, wherein:
the bent portion is plural; and
the plurality of bent portions are repeatedly disposed along an air flow path direction.

20. The thermoelectric module of claim 6, wherein:
the bent portion is plural; and
the plurality of bent portions are repeatedly disposed along a direction from the first substrate to the first heat transfer member or a direction from the second substrate to the second heat transfer member.
